(19) United States
(12) Patent Application Publication
(10) Pub. No.: US 2009/0081847 A1
(43) Pub. Date: Mar. 26, 2009

(54) METHOD OF MANUFACTURING NONVOLATILE SEMICONDUCTOR MEMORY DEVICE

(75) Inventor: Hiroshi KUBOTA, Mie-Ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/234,098

(22) Filed: Sep. 19, 2008

(30) Foreign Application Priority Data
Sep. 20, 2007 (JP) 2007-243742

(51) Int. Cl. H01L 21/76

(52) U.S. Cl. 438/424; 257/E21.546

(57) ABSTRACT

A method of manufacturing a nonvolatile semiconductor memory device comprising: forming a trench in a silicon substrate; forming a silicon dioxide film along an internal surface of the trench of the silicon substrate; removing the silicon dioxide film formed on a bottom surface of the trench of the silicon substrate by an anisotropic etching process; and forming an ozone tetraethyl orthosilicate (O₃-TEOS) film on an inner side of the silicon dioxide film by selectively depositing the O₃-TEOS film on the bottom surface of the trench of the silicon substrate by a thermal CVD method.

### CROSS-REFERENCE TO RELATED APPLICATION

This application is based upon and claims the benefit of priority from the prior Japanese Patent Application No. 2007-243742, filed Sep. 20, 2007, the entire contents of which are incorporated herein by reference.

### FIELD OF THE INVENTION

The present invention relates to a nonvolatile semiconductor memory device manufacturing method for burying a device isolation insulating film in a trench formed in a semiconductor substrate.

### DESCRIPTION OF THE BACKGROUND

In recent years, a shallow trench isolation (STI) technique has been used as a method of achieving device isolation in a semiconductor substrate. Such an STI technique is known as a device isolation technique for forming a trench in a semiconductor substrate first firstly, and then for burying a device isolation insulating film in the trench. Heretofore, a high density plasma chemical vapor deposition (HDP-CVD) method has been used for burying an oxide film in a trench formed in a semiconductor substrate (for example, refer to Japanese Patent Application Publication No. Hei 11-317443 (hereinafter, referred to as Patent Document 1)).

Although Patent Document 1 discusses use of ozone tetraethyl orthosilicate (O₃-TEOS), the technique disclosed in Patent Document 1 still involves formation of an air gap such as a seam or void in the device isolation insulating film. This is because a burying technique used for an STI trench has a greater difficulty than ever as the size reduction of a device advances. If such an air gap is formed in a device isolation insulating film, the device isolation film may be etched by a larger amount than necessary during an etching process, which is performed later. Such an increase in the amount of etching causes an enlargement of the air gap, which leads to degradation in reliability. Although it is possible to remove such an air gap by performing a different process (such as a high temperature steam oxidation process), the process may have negative influence on a different region.

An object of the present invention is to provide a method of manufacturing a nonvolatile semiconductor memory device including a device isolation insulating film formed in a device isolation trench without forming an air gap therein.

### SUMMARY OF THE INVENTION

According to an aspect of the present invention, a method of manufacturing a nonvolatile semiconductor memory device comprising: forming a trench in a silicon substrate; forming a silicon dioxide film along an internal surface of the trench of the silicon substrate; removing the silicon dioxide film formed on a bottom surface of the trench of the silicon substrate by an anisotropic etching process; and forming an ozone tetraethyl orthosilicate (O₃-TEOS) film on an inner side of the silicon dioxide film by selectively depositing the O₃-TEOS film on the bottom surface of the trench of the silicon substrate by a thermal CVD method.

According to an aspect of the present invention, a method of manufacturing a semiconductor device comprising: forming a trench including a bottom surface and a side surface in a device isolation region of a semiconductor substrate having, on a top surface of the semiconductor substrate, a first active region, a second active region distant from the first active region and the device isolation region provided between the first active region and the second active region; and selectively burying an O₃-TEOS film in the trench by a thermal CVD method under a condition in which a deposition rate on the bottom surface of the trench is greater than a deposition rate on the side surface thereof.

According to an aspect of the present invention, a method of manufacturing a semiconductor device comprising: forming a gate insulating film on a top surface of a silicon substrate; forming a semiconductor layer on the gate insulating film; forming a stopper film on the semiconductor layer; forming a mask layer selectively on a portion corresponding to an active region of the stopper film, the mask layer extending in a first direction; forming a trench having a side surface and a bottom surface in a device isolation region of the silicon substrate by removing a portion of the stopper film, the semiconductor layer, the gate insulating film and the silicon substrate, which portion corresponds to the device isolation region, by performing an anisotropic etching process using the mask layer as the mask; forming a silicon dioxide film on an upper surface and a side surface of the mask layer, a side surface of the stopper film, a side surface of the semiconductor layer, a side surface of the gate insulating film and the side surface and the bottom surface of the trench; exposing the silicon substrate from the bottom surface of the trench by selectively removing the silicon dioxide film formed on the upper surface of the mask layer and the bottom surface of the trench; depositing an O₃-TEOS film on the silicon substrate exposed from the bottom surface of the trench until an upper surface of the O₃-TEOS film becomes higher than the upper surface of the mask layer; exposing the upper surface of the stopper film by polishing the O₃-TEOS film, the silicon dioxide film and the mask layer; exposing an upper surface and an upper side surface of the semiconductor layer by removing the stopper film, a portion of the silicon dioxide film and a portion of the O₃-TEOS film by an etching process; forming an inter-gate insulating film on an upper surface of the O₃-TEOS film and the exposed upper surface and upper side surface of the semiconductor layer; forming a conductive layer on the inter-gate insulating film; forming a plurality of gate electrodes each including the conductive layer isolated by an isolation region obtained by selectively removing the conductive layer, the inter-gate insulating film and the semiconductor layer by use of a mask pattern extending in a second direction orthogonal to the first direction; and ion-implanting an impurity selectively into the active region of the silicon substrate corresponding to the isolation region.

### BRIEF DESCRIPTION OF THE DRAWINGS

FIG. 1 is a plan view schematically showing a structure of a memory cell region in a nonvolatile semiconductor memory device according to an embodiment of the present invention.

FIG. 2A is a cross sectional view schematically showing the structure of the memory cell region of FIG. 1 along the word line direction (a cross sectional view taken along the line A-A of FIG. 1).

FIG. 2B is a cross sectional view schematically showing the structure of the memory cell region of FIG. 1 in the bit line direction (a cross sectional view taken along the line B-B of FIG. 1).

FIG. 3 is a cross sectional view schematically showing a manufacturing phase (part 1).

FIG. 4 is a cross sectional view schematically showing a manufacturing phase (part 2).

FIG. 5 is a cross sectional view schematically showing a manufacturing phase (part 3).

FIG. 6 is a cross sectional view schematically showing a manufacturing phase (part 4).

FIG. 7 is a cross sectional view schematically showing a manufacturing phase (part 5).

FIG. 8 is a cross sectional view schematically showing a manufacturing phase (part 6).

FIG. 9 is a cross sectional view schematically showing a manufacturing phase (part 7).

FIG. 10 is a cross sectional view schematically showing a manufacturing phase (part 8).

FIG. 11 is a cross sectional view schematically showing a manufacturing phase (part 9).

FIG. 12 is a cross sectional view schematically showing a manufacturing phase (part 10).

FIG. 13 is a diagram showing selective growth performance data (part 1).

FIG. 14 is a diagram showing selective growth performance data (part 2).

FIG. 15 is a diagram showing selective growth performance data (part 3).

FIG. 16 is a diagram showing selective growth performance data (part 4).

FIG. 17 is a diagram showing selective growth performance data (part 5).

### DETAILED DESCRIPTION OF THE INVENTION

Embodiments of the present invention will be described hereinafter with reference to the drawings. In the descriptions of the drawings, the same or similar portions are denoted by the same or the similar reference numerals. The drawings are schematic representations, however, so that the relations between the thicknesses and planner dimensions, and the ratios of the thicknesses of the layers are different from actual ones.

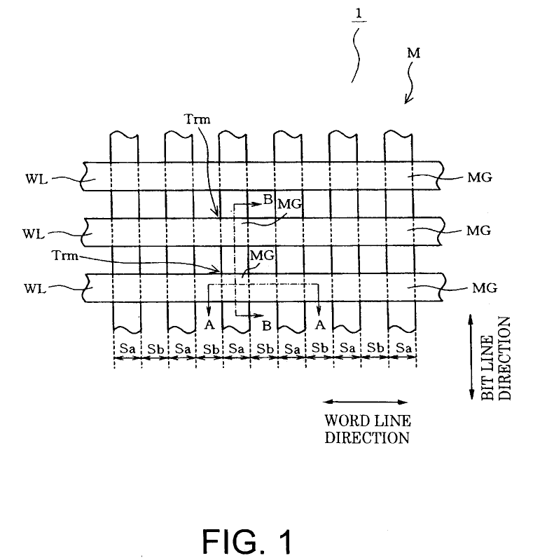

FIG. 1 schematically shows a plan view of a memory cell region of a nonvolatile semiconductor memory device.

As shown in FIG. 1, in the memory cell region M of the nonvolatile semiconductor memory device 1, a large number of memory cell transistors Trm are arraigned in a matrix in the word line direction and in the bit line direction. In addition, the memory cell transistors Trm are configured in a manner that the data stored and retained therein can be read, written and deleted by an unillustrated peripheral circuit. As an example of a nonvolatile semiconductor memory device having such a memory cell arrangement structure, a NAND-type flash memory having a cell unit structure including multiple memory cell transistors connected in series between two selective gate transistors can be cited.

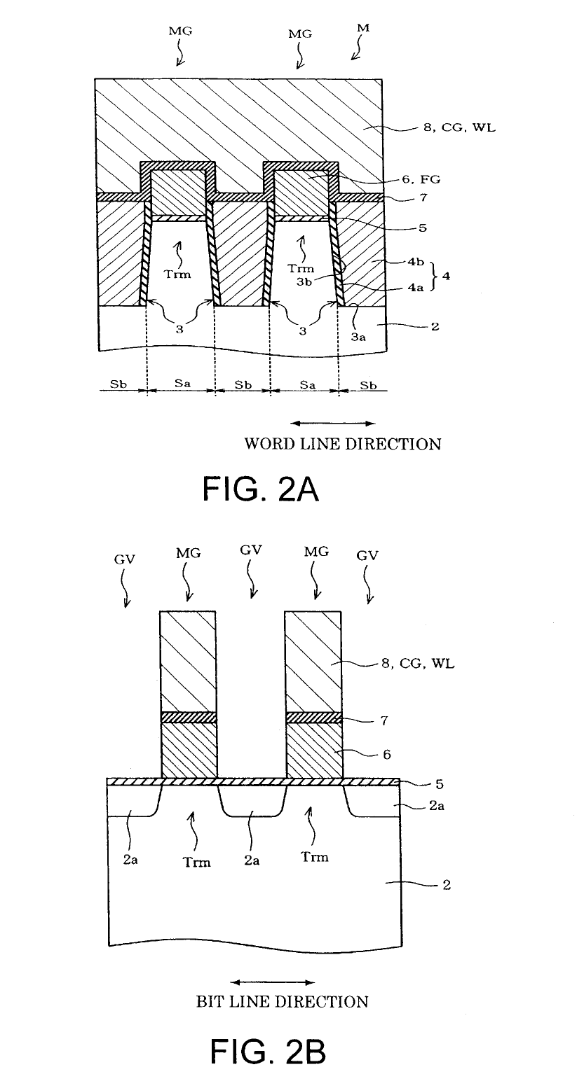

FIG. 2A shows a cross sectional view taken along in the word line direction of each of the memory cells (a cross sectional view taken along the line A-A of FIG. 1). FIG. 2B shows a cross sectional view taken along in the bit line direction of each of the memory cells (a cross sectional view taken along the line B-B of FIG. 1). As shown in FIG. 2A, a well region is formed in an upper portion of a p-type single crystal silicon substrate 2 (not shown), and a plurality of device isolation trenches 3 are formed on a surface layer of the well region. These device isolation trenches 3 are formed so as to isolate a plurality of active regions Sa in the word line direction shown in FIG. 2A. A device isolation insulating film 4 is formed in side of each of the device isolation trenches 3. The device isolation insulating film 4 is formed, so that the top portion of the device isolation insulating film 4 protrudes from the top surface of the silicon substrate 2 in an upper direction.

Agate insulating film 5 is formed on each of the plurality of active regions Sa of the silicon substrate 2. The gate insulating film 5 is formed of a silicon dioxide film. The side surface of each of the gate insulating films 5 is in contact with part of an upper side surface of the device isolation insulating film 4. A conductive layer 6 is formed on each of these gate insulating films 5. This conductive layer 6 is formed of polycrystalline silicon doped with an impurity such as phosphorus, and functions as a floating gate electrode FG. The conductive layer 6 is disposed in contact with the side surface of the device isolation insulating film 4, which protrudes from the top surface of the silicon substrate 2 in the upper direction. In addition, the conductive layer 6 is formed, so that the top surface of the conductive layer 6 protrudes from the upper edge of the device isolation insulating film 4 in an upper direction. The side surface of the device isolation insulating film 4, which protrudes from the silicon substrate 2 in the upper direction, is formed, so that the side surface thereof with the side surface of the gate insulating films 5 and a lower side surface of the conductive layer 6 are a single surface.

The device isolation insulating film 4 is formed of a high temperature oxide (HTO) film 4a and an O₃-TEOS (tetraethyl orthosilicate) film 4b formed at an inner side of the HTO film 4a and in the device isolation trench 3. The HTO film 4a is formed along a side wall surface 3b of the device isolation trench 3. The O₃-TEOS film 4b is formed in an area from a bottom surface 3a (the bottom surface part of the trench) of the device isolation trench 3a positioned between the HTO films 4a up to an area above the top surface of the silicon substrate 2.

An inter-gate insulating film 7 is formed along the top surfaces of the device isolation insulating films 4, the upper side surfaces and the top surfaces of the conductive layers 6. This inter-gate insulating film 7 is formed of a silicon dioxide film, a high dielectric constant insulating film and a silicon dioxide film in the order of the lower layer to the upper layer, and functions as an inter-conductive-layer insulating film. The high dielectric constant insulating film is formed of a film having a relative dielectric constant greater than that of a silicon dioxide film (such as a silicon nitride film or a film of aluminum oxide (Al₂O₃), for example)

A conductive layer 8 is formed on the inter-gate insulating film 7 along the word line direction. The conductive layer 8 is formed of polycrystalline silicon and a metal silicide layer formed directly on top of the polycrystalline silicon (neither is shown). The metal silicide layer is obtained by depositing a metal such as tungsten or cobalt on the polycrystalline silicon and causing the metal to react with the polycrystalline silicon. In the manner described above, a gate electrode MG of the memory cell transistor Trm including a laminated structure formed of the conductive layer 6, the inter-gate insulating film 7 and the conductive layer 8 is formed.

As shown in FIG. 2B, the gate electrodes MG of the memory transistors Trm are arranged in parallel with each other in the bit line direction. In addition, the gate electrodes MG are electrically isolated from each other by an isolation region GV. Incidentally, although it is not shown, an interlayer insulating film, a barrier film for suppressing impurities from passing therethrough, or the like is deposited and formed in the isolation region GV.

Source/drain regions 2a are formed on top surface layers of the silicon substrate 2 and at both sides of the gate electrode MG of the memory cell transistor Trm. The memory cell transistor Trm is formed of the gate insulating film 5, the gate electrode MG and the source/drain regions 2a.

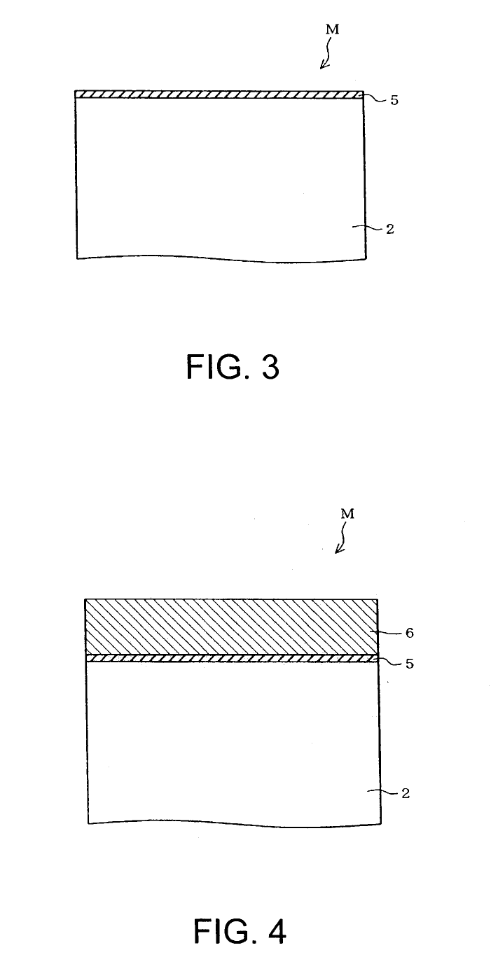

A manufacturing method of the aforementioned configuration is described with reference to FIGS. 3 to 12. Here, a manufacturing method of forming portions of the structure of the memory cell region related to features of the present embodiment will be described, and a manufacturing method of forming other regions (such as a peripheral circuit region, for example) is omitted.

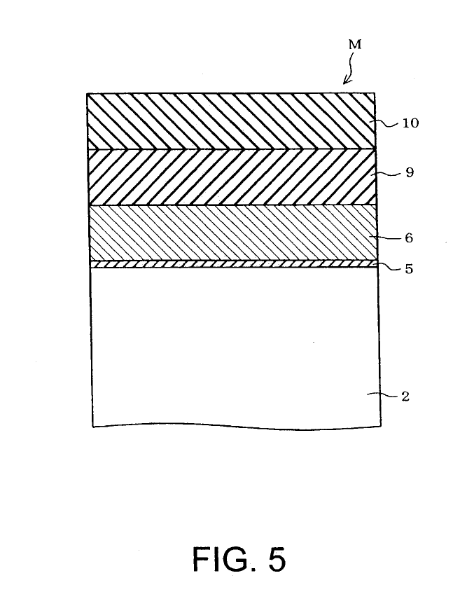

A well region (not shown) is formed in an upper portion of the silicon substrate 2, and the gate insulating film 5 is formed as a tunnel insulating film on a primary surface of the silicon substrate 2 by a thermal oxidation process. Next, as shown in FIG. 4, the polycrystalline silicon layer 6 doped with an impurity such as phosphorus is deposited on the gate insulating film 5 by a chemical vapor deposition (CVD) method. Next, as shown in FIG. 5, the silicon nitride film 9 is deposited on the polycrystalline silicon layer 6 by a CVD method. Then, a silicon dioxide film 10 is deposited on the silicon nitride film 9 as a hard mask.

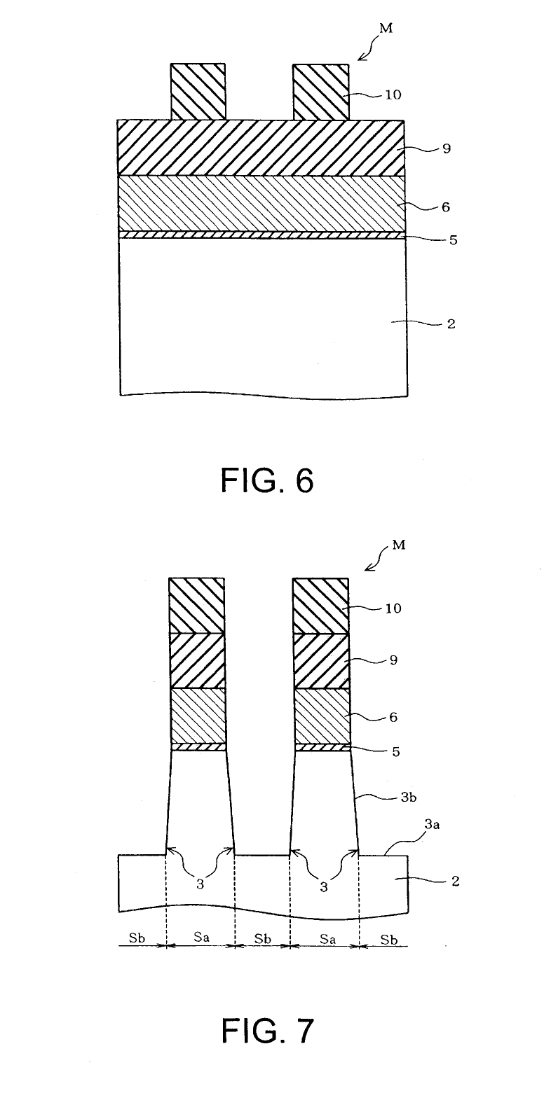

Next, as shown in FIG. 6, a resist (not shown) is applied on the silicon dioxide film 10, and then, the resist is patterned. The silicon dioxide film 10 is processed by a reactive ion etching (RIE) method by using the patterned resist as the mask. Next, the resist is removed by an ashing process or a process using a mixture of sulfuric acid and hydrogen peroxide solution.

As shown in FIG. 7, the device isolation trench 3 (trench) is formed in the silicon substrate 2 by sequentially performing an anisotropic etching process using an RIE method on the silicon nitride film 9, the polycrystalline silicon layer 6, the gate insulating film 5 and an upper portion of the silicon substrate 2 by use of the silicon dioxide film 10 as the hard mask. Next, reaction products formed during the RIE process are removed by a dilute hydrofluoric acid process or the like. Thereby, the active region Sa and the device isolation region Sb are sectioned.

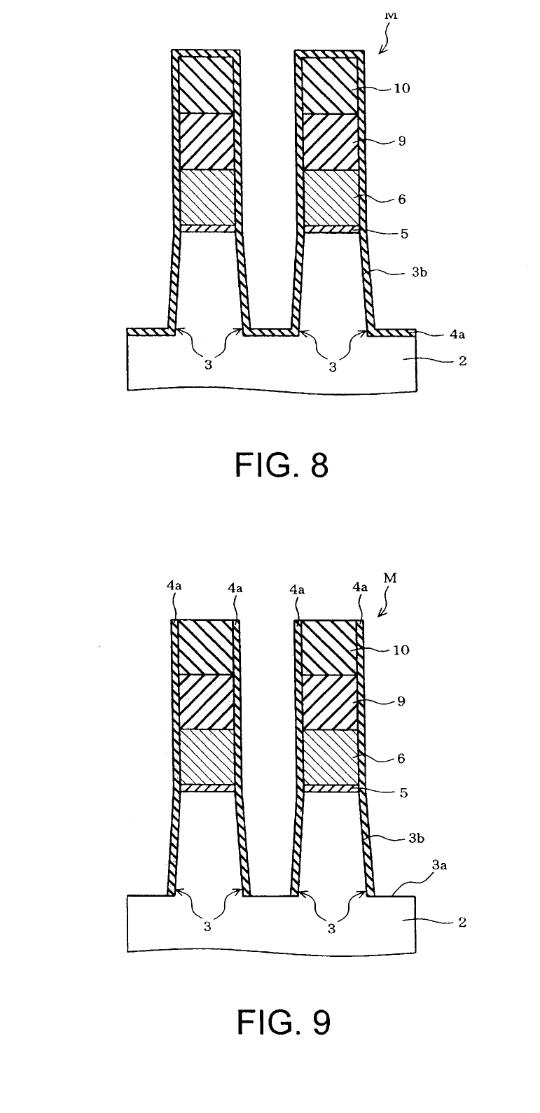

Next, as shown in FIG. 8, the HTO film 4a is isotropically deposited on the top surface and side surface of the silicon dioxide film 10, the side surface of the silicon nitride film 9, the side surface of the polycrystalline silicon layer 6, the side surface of the gate insulating film 5 and the top surface of the device isolation trench 3 by a low pressure thermal CVD method using a mixed gas of dichlorosilane (SiH₂Cl₂) and nitrous oxide (N₂O).

Next, as shown in FIG. 9, the HTO film 4a formed at a center portion of the bottom surface 3a of the device isolation trench 3 is removed by an anisotropic etching process using an RIE method. Thereby, the center portion of the bottom surface 3a of the device isolation trench 3 is exposed. As a result of the aforementioned process, the HTO film 4a remains along the side wall surface 3b of the device isolation trench 3 only in each of the device isolation trenches 3 of the silicon substrate 2. At this time, the HTO film 4a formed on the upper surface of the silicon dioxide film 10 is also removed.

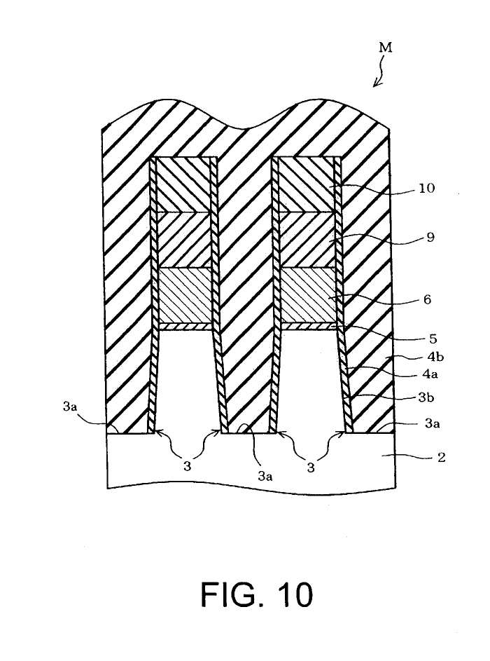

Next, as shown in FIG. 10, the O₃-TEOS film 4b is formed on the silicon substrate 2 as the base under a low temperature condition by a thermal CVD method. The deposition (growth) rate of the O₃-TEOS film 4b when the film is deposited on a surface in contact with the silicon substrate 2 (silicon) is faster than that when the film is deposited on a surface in contact with the HTO film 4a (silicon dioxide film). Accordingly, the O₃-TEOS film 4b is selectively deposited on the bottom surface 3a of the device isolation trench 3.

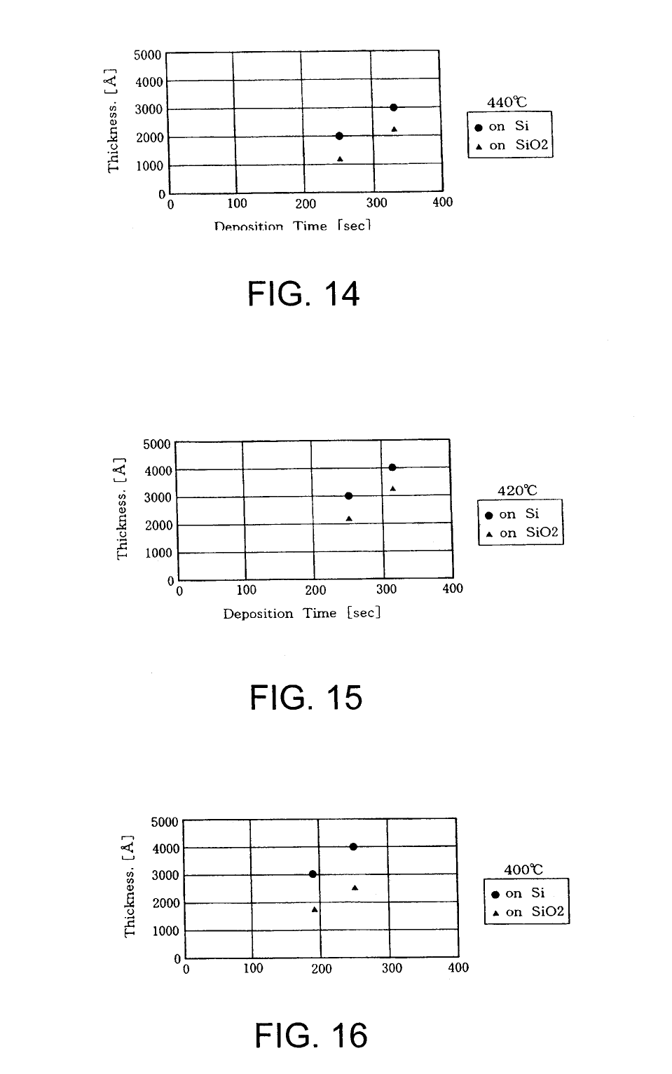

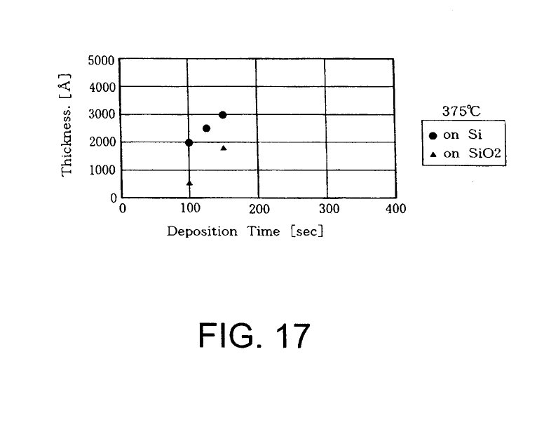

FIGS. 13 to 17 show results of an experiment when the inventors conducted the experiment of deposition of the O₃-TEOS film 4b. The FIGS. 13 to 17 show film thickness data with respect to deposition time at the temperatures of 480° C. (FIG. 13), 440° C. (FIG. 14), 420° C. (FIG. 15), 400° C. (FIG. 16) and 375° C. (FIG. 17). As shown in FIGS. 13 to 17, by comparing the film thickness data (on Si) of a case where the film is deposited on silicon with the film thickness data (on SiO2) of a case where the film is deposited on silicon dioxide film, it can be confirmed that the lower the temperature condition, the greater the selective growth characteristics. Specifically, the selective growth characteristics can be greater when the film is deposited under a temperature condition of not higher than 500° C. (preferably, not higher than 480° C., even not higher than 440° C., even not higher than 420° C., even not higher than 400° C., and 375° C.).

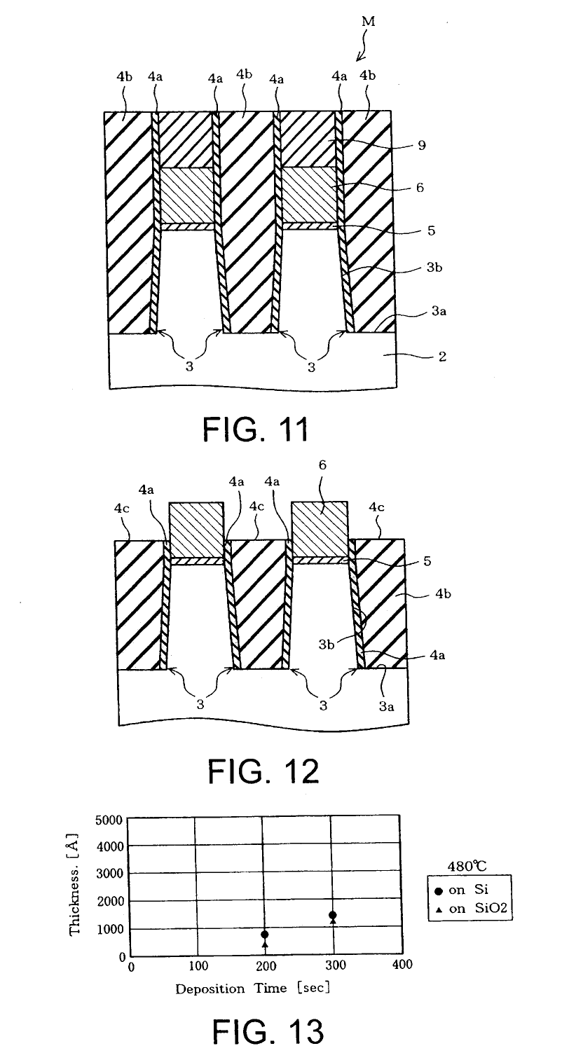

Next, as shown in FIG. 11, a planarization process using a chemical polishing planarization (CMP) method is performed on the upper portion of the device isolation insulating film 4 (the HTO film 4a and O₃-TEOS film 4b) with the silicon nitride film 9 as the stopper.

Next, as shown in FIG. 12, the upper surfaces of the polycrystalline silicon layers 6 are exposed by removing the silicon nitride films 9 by an etching process using a chemical solution or the like. Then, the upper portion of the device isolation insulating film 4 is removed by an etching process with a dilute hydrofluoric acid solution. At this time, the device isolation insulating film 4 is formed so that the upper surface 4c of the device isolation insulating film 4 can be positioned below the upper surface of the polycrystalline silicon layer 6 and above the upper surface of the gate insulating film 5. As a result, the upper surface and the upper side surface of the polycrystalline silicon layer 6 are exposed.

Next, as shown in FIG. 2A, the inter-gate insulating film 7 is formed by forming a silicon dioxide film, a high dielectric constant insulating film and a silicon dioxide film from the lower layer to the upper layer by a low pressure CVD method. Next, a conductive layer 8 is formed by depositing polycrystalline silicon on the inter-gate insulating film 7 by a CVD method. Next, a mask pattern (not shown) is formed on the conductive layer 8, and among the laminated films 5 to 8, the conductive layer 8, the inter-gate insulating film 7 and the conductive layer 6 are etched in a direction parallel to the surface shown in FIG. 2A by use of an anisotropic etching technique such as an RIE method and thus cut in a direction perpendicular to the surface shown in FIG. 2A and isolated. As a result, as shown in FIG. 2B, isolation regions GV each isolating the gate electrodes MG are formed.

Next, as shown in FIG. 2B, from the isolation region GV, an impurity for forming the source/drain region 2a on the top surface of the silicon substrate 2 is ion-implanted. Thereafter, an interlayer insulating film (not shown) is deposited in each of the isolation regions GV. Then, the manufacturing phase shifts to an upper layer interconnection forming process after contact elements for various interconnections are formed in the interlayer insulating film. However, the detailed description thereof is omitted here since the manufacturing phase is not directly related to features of the present embodiment. It should be noted that a silicide formation process of an upper portion of the conductive layer 8 may be performed at the timing before or after the gate electrodes MG are isolated by the isolation regions GV, depending on a metal material or the like to be applied.

When an air gap is formed in the device isolation insulating film 4, the air gap needs to be buried in a different process. This is because the position of the upper surface of the device isolation insulating film 4 needs to be adjusted to a position lower than that of the upper surface of the conductive layer 6 for retaining the characteristics of the memory cell (coupling ratio), but the adjustment of the position of the upper surface of the device isolation insulating film 4 varies when an air gap is formed in the device isolation insulating film 4. The variation in the adjustment of the position of the upper surface of the device isolation insulating film 4 leads to degradation in reliability such as a variation in the characteristics of the memory cells or an increase in leak current between the memory cells. Although the device isolation insulating film 4 can be formed with high density by processing at a high temperature, a bird's beak may be generated in the gate insulating film 5.

In this respect, in this embodiment, the HTO film 4a is isotropically formed along the internal surface of the device isolation trench 3, first. Then, the HTO film 4a deposited on the center portion of the bottom surface 3a of the device isolation trench 3 is removed by an anisotropic etching using an RIE method. Thereby, the HTO film 4a remains only along the side wall surface 3b of the device isolation trench 3. The O₃-TEOS film 3b is thus selectively deposited from the center portion of the bottom surface 3a. Thereby, the device isolation insulating film 4 can be formed with high density without generating an air gap caused by a void or seam in the device isolation insulating film 4.

### Other Embodiments

The present invention is not limited to the aforementioned embodiment. For example, a modification or enhancement to be described below is also possible.

In the aforementioned embodiment, the HTO film 4a is formed along the internal surface of the device isolation trench 3 by a low pressure thermal CVD method. However, a silicon dioxide film may be formed along the internal surface of the device isolation trench 3 by a plasma enhanced (PE) CVD (chemical vapor deposition) method or a high density plasma (HDP) CVD method instead of the low pressure thermal CVD method.

What is claimed is:

1. A method of manufacturing a nonvolatile semiconductor memory device comprising:
forming a trench in a silicon substrate;
forming a silicon dioxide film along an internal surface of the trench of the silicon substrate;
removing the silicon dioxide film formed on a bottom surface of the trench of the silicon substrate by an anisotropic etching process; and
forming an ozone tetraethyl orthosilicate (O₃-TEOS) film on an inner side of the silicon dioxide film by selectively depositing the O₃-TEOS film on the bottom surface of the trench of the silicon substrate by a thermal CVD method.

2. The method of manufacturing a nonvolatile semiconductor memory device according to claim 1, wherein the O₃-TEOS film is formed under a temperature condition of not higher than 500° C.

3. The method of manufacturing a nonvolatile semiconductor memory device according to claim 1, wherein a high temperature oxide (HTO) film formed by a thermal CVD method is applied as the silicon dioxide film.

4. The method of manufacturing a nonvolatile semiconductor memory device according to claim 2, wherein a high temperature oxide (HTO) film formed by a thermal CVD method is applied as the silicon dioxide film.

5. A method of manufacturing a semiconductor device comprising:
forming a trench including a bottom surface and a side surface in a device isolation region of a semiconductor substrate having, on a top surface of the semiconductor substrate, a first active region, a second active region distant from the first active region and the device isolation region provided between the first active region and the second active region; and
selectively burying an O₃-TEOS film in the trench by a thermal CVD method under a condition in which a deposition rate on the bottom surface of the trench is greater than a deposition rate on the side surface thereof.

6. The method of manufacturing a semiconductor device according to claim 5, further comprising a step of forming memory cell transistors respectively in the first and second active regions.

7. The method of manufacturing a semiconductor device according to claim 5, further comprising selectively forming a silicon dioxide film on the side surface of the trench between the forming the trench and the selectively burying the O₃-TEOS film.

8. The method of manufacturing a semiconductor device according to claim 7, wherein the selectively forming the silicon dioxide film includes the steps of:
forming a silicon oxide film on the bottom surface and the side surface; and
exposing the silicon substrate from the bottom surface by selectively removing the silicon dioxide film formed on the bottom surface.

9. The method of manufacturing a semiconductor device according to claim 8, wherein the silicon dioxide film is an HTO film deposited and formed by a thermal CVD method.

10. A method of manufacturing a semiconductor device comprising:
forming a gate insulating film on a top surface of a silicon substrate;
forming a semiconductor layer on the gate insulating film;
forming a stopper film on the semiconductor layer;
forming a mask layer selectively on a portion corresponding to an active region of the stopper film, the mask layer extending in a first direction;
forming a trench having a side surface and a bottom surface in a device isolation region of the silicon substrate by removing a portion of the stopper film, the semiconductor layer, the gate insulating film and the silicon substrate, which portion corresponds to the device isolation region, by performing an anisotropic etching process using the mask layer as the mask;
forming a silicon dioxide film on an upper surface and a side surface of the mask layer, a side surface of the stopper film, a side surface of the semiconductor layer, a side surface of the gate insulating film and the side surface and the bottom surface of the trench;
exposing the silicon substrate from the bottom surface of the trench by selectively removing the silicon dioxide film formed on the upper surface of the mask layer and the bottom surface of the trench;
depositing an O₃-TEOS film on the silicon substrate exposed from the bottom surface of the trench until an upper surface of the O₃-TEOS film becomes higher than the upper surface of the mask layer;
exposing the upper surface of the stopper film by polishing the O₃-TEOS film, the silicon dioxide film and the mask layer;
exposing an upper surface and an upper side surface of the semiconductor layer by removing the stopper film, a portion of the silicon dioxide film and a portion of the O₃-TEOS film by an etching process;
forming an inter-gate insulating film on an upper surface of the O₃-TEOS film and the exposed upper surface and upper side surface of the semiconductor layer;
forming a conductive layer on the inter-gate insulating film;
forming a plurality of gate electrodes each including the conductive layer isolated by an isolation region obtained by selectively removing the conductive layer, the inter-gate insulating film and the semiconductor layer by use of a mask pattern extending in a second direction orthogonal to the first direction; and
ion-implanting an impurity selectively into the active region of the silicon substrate corresponding to the isolation region.

11. The method of manufacturing a semiconductor device according to claim 10, wherein the step of forming the gate insulating film includes a step of forming the silicon dioxide film by thermal oxidation.

12. The method of manufacturing a semiconductor device according to claim 10, wherein the semiconductor layer is a polycrystalline silicon layer doped with an impurity.

13. The method of manufacturing a semiconductor device according to claim 12, wherein the semiconductor layer is formed by a CVD method.

14. The method of manufacturing a semiconductor device according to claim 10, wherein the stopper film is a silicon nitride film.

15. The method of manufacturing a semiconductor device according to claim 10, wherein the silicon dioxide film is an HTO film formed by a thermal CVD method.

16. The method of manufacturing a semiconductor device according to claim 10, wherein the step of depositing the O₃-TEOS film is a step of depositing the O₃-TEOS film by a thermal CVD method at a film-forming temperature of not higher than 500° C.

17. The method of manufacturing a semiconductor device according to claim 10, wherein the inter-gate insulating film is a laminated film obtained by laminating a silicon dioxide film, a high dielectric constant insulating film and a silicon dioxide film.

18. The method of manufacturing a semiconductor device according to claim 10, wherein the conductive layer is a polycrystalline silicon layer.
